(19) United States
(12) Patent Application Publication
(10) Pub. No.: US 2011/0048799 A1
(43) Pub. Date: Mar. 3, 2011

(54) Microstructure and Process for its Assembly

(75) Inventors: Sebastian Kisban, Munchen (DE); Stanislav Herwik, Rheinfelden (DE); Patrick Ruther, Karlsruhe (DE); Tobias Holzhammer, Freiburg (DE); Oliver Paul, Au (DE)

(73) Assignee: ALBERT-LUDWIGS-UNIVERSITAT FREIBURG, Freiburg (DE)

(21) Appl. No.: 12/857,737

(22) Filed: Aug. 17, 2010

(30) Foreign Application Priority Data
Aug. 18, 2009 (DE) 10 2009 037 802.2

(51) Int. Cl. H02G 3/00; B81C 1/00

(52) U.S. Cl. 174/70 R; 29/592.1

(57) ABSTRACT

In a process for assembling a microstructure (1), provision is made of a first microstructure piece (2) having a receiving recess (3) in its surface and a second microstructure piece (5) having a connecting region (6) fitting into the receiving recess (3) and on which is arranged at least one electrical contact element (7a, 7b). Provision is made of a flexible cable (8) having a flat substrate layer (9) made of an electrically insulating material and at least one strip conductor (10) arranged thereon. The cable (8) has at least one tongue (14a, 14b) on which is arranged at least one counter-contact element (11a, 11b) connected to the strip conductor (10). The cable (8) and the microstructure pieces (5) are positioned relative to each other in a preassembly position in which the connecting region (6) is opposite the receiving recess (3) and the tongue (14a, 14b) is aligned between the connecting region (6) and the receiving recess (3). The connecting region (6) is then introduced in the receiving recess (3) by displacement of the microstructure pieces (2, 5) toward one another. In doing so the at least one tongue (14a, 14b) is deflected in the receiving recess (3) in such a way that the at least one counter-contact element (11a, 11b) contacts the at least one contact element (7a, 7b).

The invention relates to a microstructure with a first microstructure piece in the surface of which is formed at least one receiving recess, with at least one second microstructure piece having a connecting region engaging in the receiving recess and on which is arranged at least one electrical contact element, with at least one tongue having at least one counter-contact element arranged between the connecting region and a side wall of the receiving recess facing the latter in such a way that the contact element of the connecting region contacts the counter-contact element of the tongue with a flexible cable having at least one flat substrate layer made of an electrically insulating material and at least one strip conductor electrically connected to the counter-contact element arranged thereon and which is connected at a place spaced apart from the tongue to an electric circuit spaced apart from the first microstructure piece. The invention further relates to a process for assembling a microstructure.

Such a process is disclosed in EP 1 985 579 A2. In the process, provision is made of a first microstructure piece having a surface in which are formed several approximately rectangular receiving recesses with electrically insulated boundary walls. On each rim of each receiving recess on the first microstructure piece are arranged several tongues, which overlap a partial area of the respective receiving recess with their free ends. The tongues have counter-contact elements that are connected via strip conductors to the contact terminals arranged on the first microstructure piece. The contact terminals are connected via an ultraflexible cable to an electric circuit remotely arranged relative to the first microstructure piece.

For manufacturing the first microstructure piece, provision is initially made of a substrate on which a photomask is applied, which photomask has interruptions at the places where the receiving recesses will eventually be formed. The receiving recesses are then etched into the substrate. In another process step, the recesses are filled with a sacrificial layer. The surface of the configuration thus obtained is made level by removing material and then tongues are formed on the surface by depositing metal. A first tongue segment is arranged on the surface of the substrate and a second tongue segment is arranged on the sacrificial layer. At this point the sacrificial layer is removed. The first tongue segment remains connected to the substrate, whereas the second tongue segment overlaps the receiving recess at a distance from the floor thereof.

Further provision is made of a second microstructure piece, which has connecting regions fitting into the receiving recesses and needle-shaped shaft pieces arranged on said connecting regions. The shaft pieces are arranged in several rows and columns parallel to one another and are prismatically configured on each of their free ends spaced apart from their associated connecting region. On each shaft the second microstructure piece has several electrically conductive regions, each of which is electrically connected to a contact element arranged on the connecting region.

In another process step, the second microstructure piece is positioned relative to the first microstructure piece in such a way that the connecting region is opposite the receiving recess. The second microstructure piece is then displaced towards the first microstructure piece in order to introduce the connecting region in the receiving recess. The tongues are thus deflected in the receiving recess in such a way that each tongue contacts its respective associated contact element. Afterwards the microstructure pieces are attached to one another.

A disadvantage resides in the process in that the tongues are relatively laborious and time-consuming to manufacture. Furthermore, connecting the cable to the first microstructure piece involves a certain degree of effort. Hence the microstructure is relatively expensive to manufacture.

The object is therefore to create a microstructure of the aforementioned type that permits a simple and economical construction. Another object is to devise an easily carried out process for assembling a microstructure.

With regard to the process, this object is achieved by the following steps:
Provision of a first microstructure piece having a surface in which at least one receiving recess is formed,
Provision of at least one second microstructure piece having a connecting region which corresponds to the receiving recess and on which is arranged at least one electrical contact element,
Provision of a flexible cable having at least one flat substrate layer of an electrically insulating material and at least one strip conductor arranged thereon, wherein the cable has at least one tongue on which is arranged at least one counter-contact element connected to the strip conductor,
Positioning of the cable and the microstructure pieces in a preassembly position in such a way that the connecting region is opposite the receiving recess and the tongue is aligned between the connecting region and the receiving recess,
Displacement of the first microstructure piece and the second microstructure piece towards one another in such a way that the connecting region is introduced in the receiving recess and the at least one tongue is deflected in the receiving recess in such a way that the at least one counter-contact element contacts the at least one contact element, and
Attaching the first microstructure piece to the second microstructure piece.

It is thus possible to manufacture the tongues along with the cable and separately from the microstructure pieces and then position them along with the cable on the microstructure pieces. Advantageously it is thus possible to dispense with a laborious filling of the receiving recess arranged on the first microstructure piece with a sacrificial layer and with the process steps of applying the tongue on the first microstructure piece and removing the sacrificial layer. Preference is given to the dimensions of the receiving recess being within a range of 10-5000 μm and particularly within a range of 100-1000 μm.

Preference is given to positioning the flexible cable on the first microstructure piece in such a way that the at least one contact element and the at least one counter-contact element are spaced apart from the first microstructure piece by the substrate layer. The strip conductor and the counter-contact element of the tongue are then electrically insulated from the first microstructure piece by the substrate layer. The surface of the first microstructure piece facing the cable and even the entire microstructure piece can then be composed of an electrically conductive material, particularly a semiconductor material.

In a preferred embodiment of the invention, the first microstructure piece has an adhesive layer on its surface facing the cable in the preassembly position, and the first microstructure piece in the preassembly position and the cable are displaced towards one another in such a way that the cable touches and then adheres to the adhesive layer. The assembly of the microstructure is then even more easily carried out.

In another advantageous embodiment of the invention, the cable has an adhesive layer on its surface facing the first microstructure piece in the preassembly position, and the first microstructure piece in the preassembly position and the cable are displaced towards each other in such a way that the first microstructure piece touches and then adheres to the adhesive layer. This measure also enables a simple and quick assembly of the microstructure.

It is advantageous if the cable has at least one perforation, the at least one tongue being connected with the edge region thereof in such a way that it extends into the perforation and/or overlaps the latter at least area-wise, wherein the cable in the preassembly position is positioned relative to the receiving recess in such a way that the perforation overlaps the receiving recess, and wherein the connecting region, under the deflection of the tongue, is inserted through the perforation and into the receiving recess. Preference is given to the dimensions of the perforation corresponding to the cross-sectional dimensions of the connecting region, thus ensuring the attachment of the cable to the second microstructure piece in the correct position.

Preference is given to the second microstructure piece having at least one shaft piece connected to the connecting region, which shaft piece has at least one electrically conductive region that is electrically connected to the contact element. Such a microstructure can be used in neurophysiology for the intracortical, extracellular tapping of information on a neuronal network. The information can then be further processed as electrical signals.

With regard to the microstructure mentioned in the introduction, the aforementioned object is achieved by the integral configuration of the tongue with the cable.

The tongue can then be easily manufactured along with the cable and the microstructure pieces can then be processed independently of the latter. Afterwards the cable and the microstructure pieces can be easily assembled.

In an advantageous embodiment of the invention, the at least one strip conductor and the at least one counter-contact element are spaced apart from the first microstructure piece by the substrate layer. The tongue and the strip conductor are thus electrically insulated from the first microstructure piece by the substrate layer. Hence the first microstructure piece can be composed of an electrically conductive material.

In a preferred embodiment of the invention, the cable has at least one perforation that penetrates the cable perpendicular to its extension plane, wherein the tongue is aligned perpendicular to the plane spanned by the perforation and connected to an edge region of the perforation at its end remote from the conductive region. The cross-sectional dimensions of the perforation can then be adapted to the cross-sectional dimensions of the connecting region and the tongue in such a way that the perforation can be used as a positioning aid when assembling the microstructure pieces and the cable.

An adhesive layer facing the cable by means of which the cable adheres to the first microstructure piece is advantageously arranged on the first microstructure piece. The cable is then flatly and fixedly attached to the first microstructure piece via the adhesive layer.

It is advantageous if the tongue has a curvature between the edge region of the perforation and the contact element, and if the side wall of the receiving recess facing the tongue has an inclined surface and/or a step adjacent to the curvature, where the clearance between the side wall and a wall of the connecting region opposite said side wall increases from the floor of the receiving recess to the surface of the first microstructure piece. In this manner the cable is protected from excessive mechanical stress or kinking at the point where it is guided over the edge region of the perforation during the assembly of the microstructure.

In an advantageous embodiment of the invention, the cable has, on its perforation edge region spaced apart from and oppositely arranged relative to the tongue, at least one tongue element formed by a cable segment, which is arranged between the connecting region and another side wall of the receiving recess facing the latter. The connecting region is then spaced apart from the side walls of the receiving recess by the cable on both sides of the receiving recess. It is thus possible to compensate for manufacturing and/or assembly tolerances more effectively. Furthermore, the cable is attached on both sides of the receiving recess between the side walls thereof and the connecting zone, and thus better mechanically connected to the microstructure pieces.

In a preferred embodiment of the invention, the connecting zone has at least one first contact element and one second contact element arranged on sides of the connecting region facing one another, wherein the cable has a first tongue having at least one first counter-contact element on a first perforation edge region facing the first contact element and a second tongue having at least one counter-contact element on a second perforation edge region facing the second contact element, wherein the first tongue is arranged between the connecting region and a first side wall of the receiving recess in such a way that the first contact element contacts the first counter-contact element, and wherein the second tongue is arranged between the connecting region and a second side wall of the receiving recess in such a way that the second contact element contacts the second counter-contact element. Hence tongues can be arranged on both sides of the connecting region between the side wall of the receiving recess and the connecting region, whereby a correspondingly greater number of electrical connections between the strip conductors of the cable and the microstructure is possible.

In the following, illustrative embodiments of the invention are explained in greater detail with reference to the drawing. Shown are:

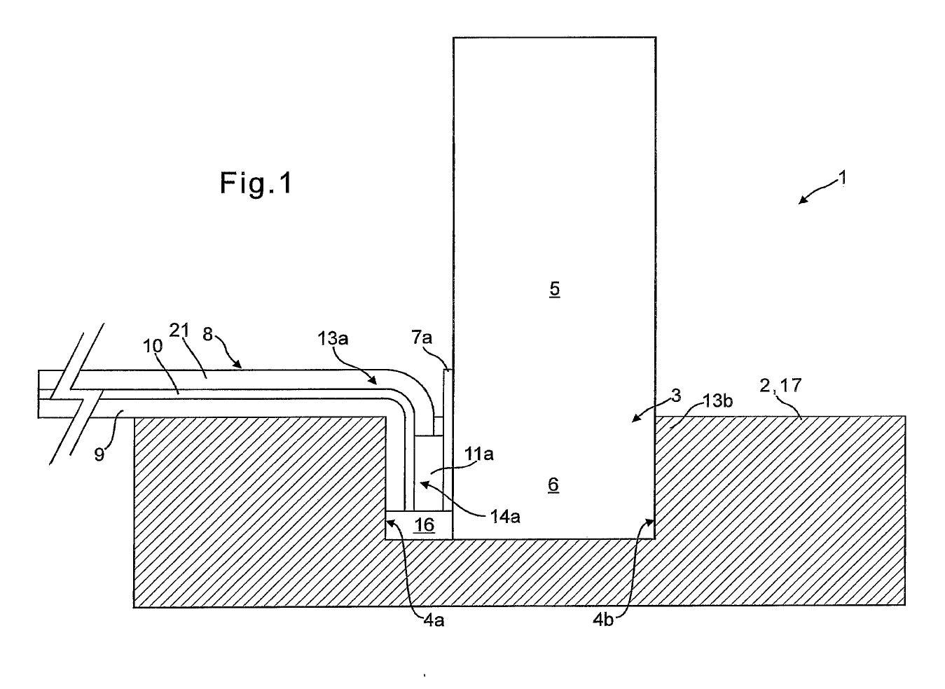

FIG. 1 a cross-section through a microstructure having a first and a second microstructure piece as well as a cable, wherein the cable and the second microstructure piece engage in a receiving recess of the first microstructure piece,

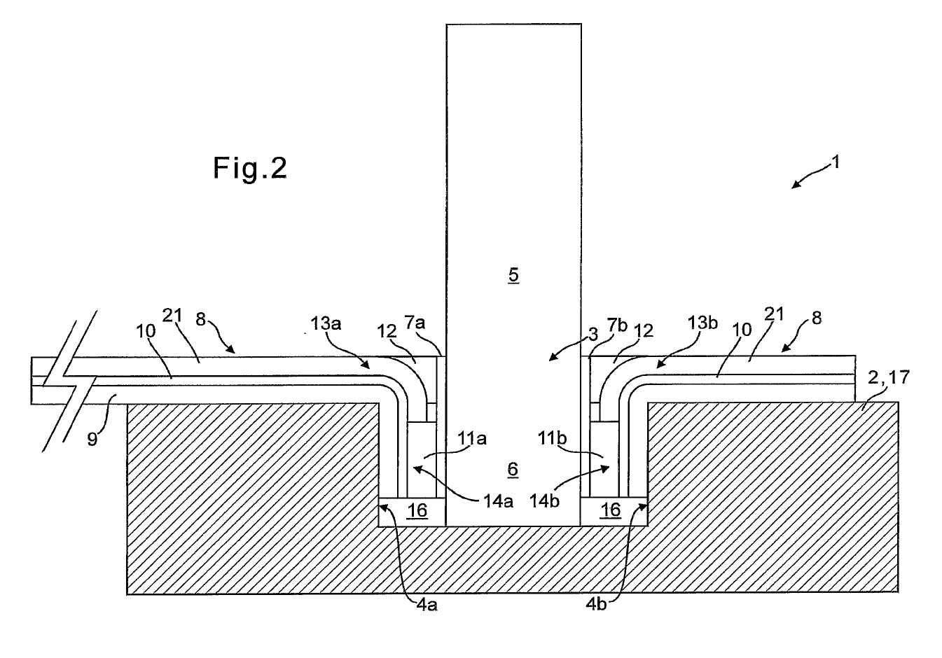

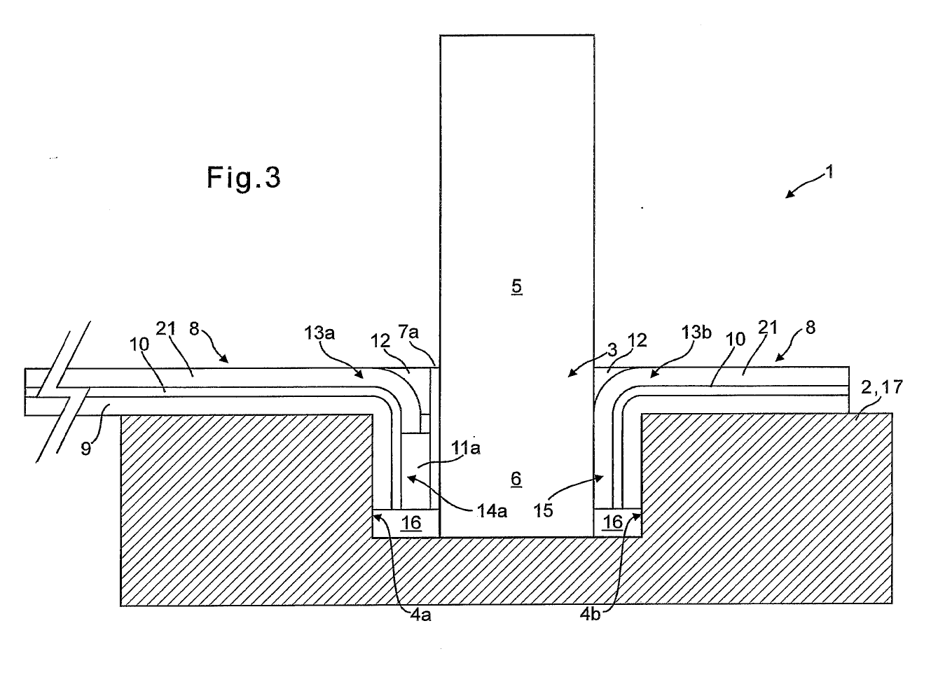

FIGS. 2 and 3 an illustration similar to FIG. 1, wherein, however, the cable engages in the receiving recess on both sides of the second microstructure piece,

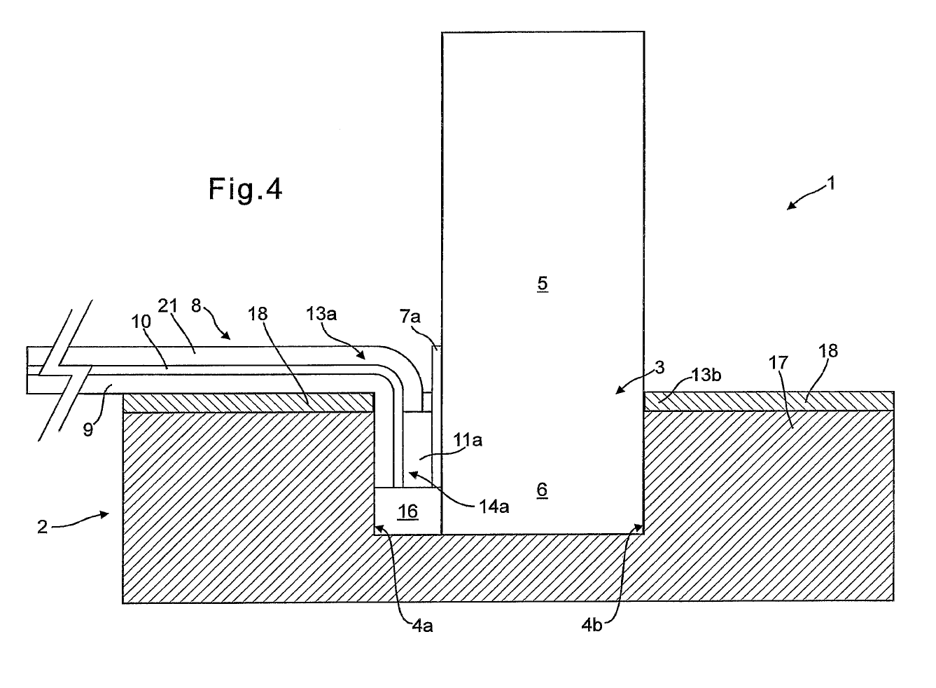

FIG. 4 an illustration similar to FIG. 1, wherein, however, an adhesive layer adhering to the cable is present on the first microstructure piece,

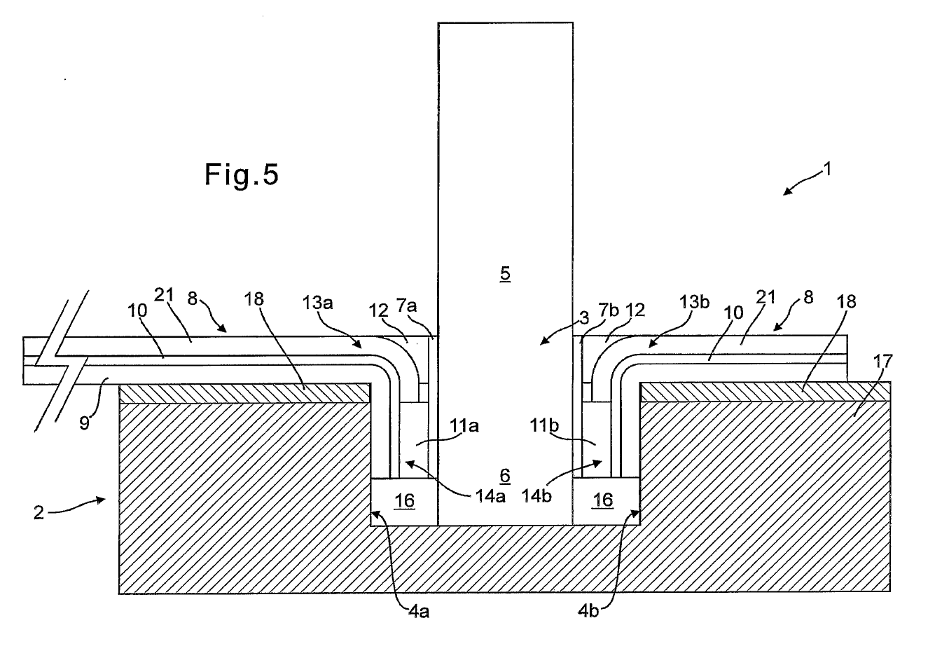

FIG. 5 an illustration similar to FIG. 2, wherein, however, an adhesive layer adhering to the cable is present on the first microstructure piece,

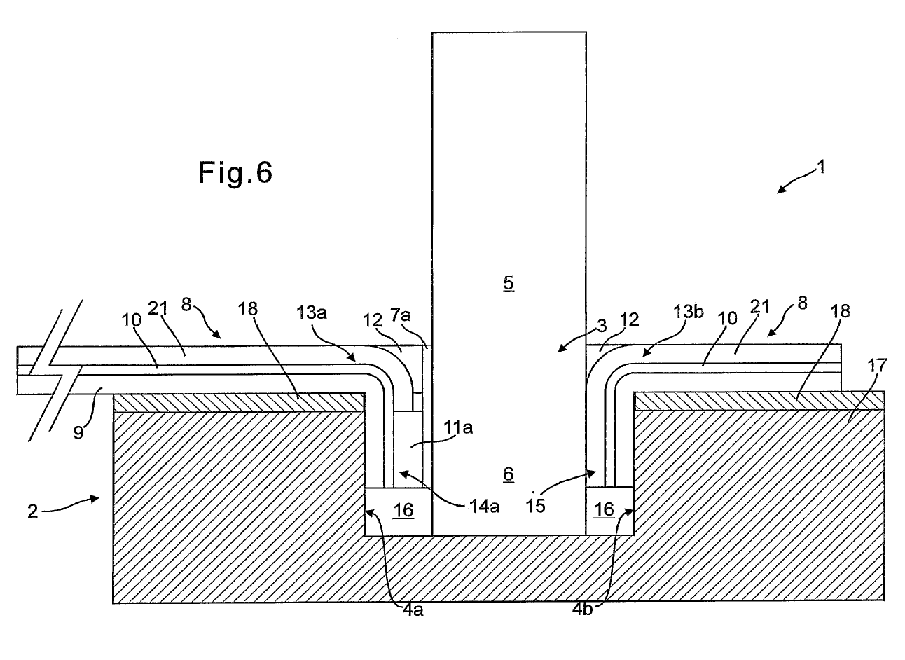

FIG. 6 an illustration similar to FIG. 3, wherein, however, an adhesive layer adhering to the cable is present on the first microstructure piece,

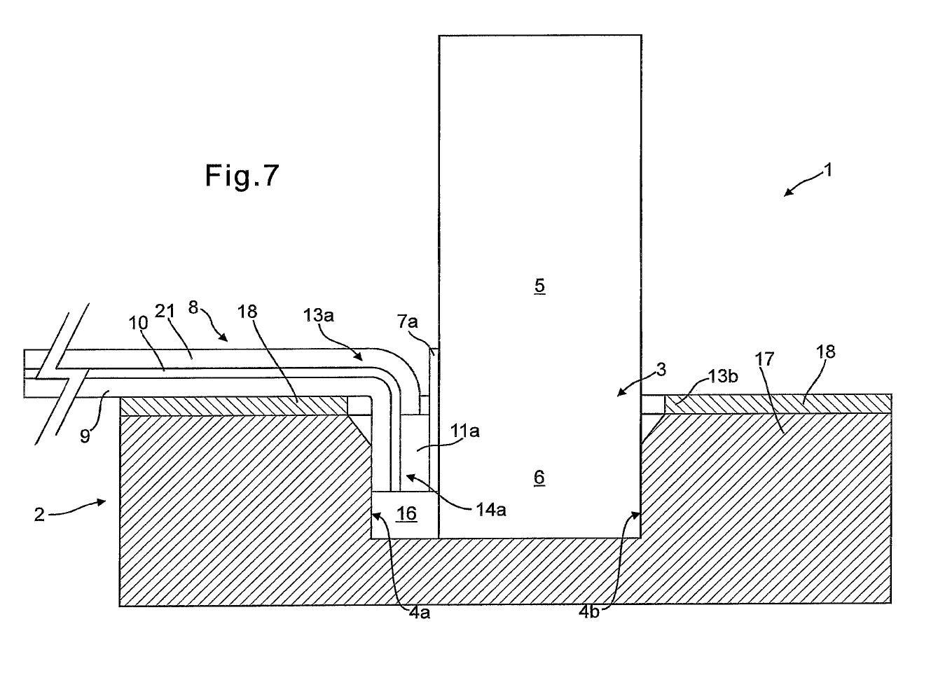

FIG. 7 an illustration similar to FIG. 4, wherein, however, the receiving recess flares upwardly,

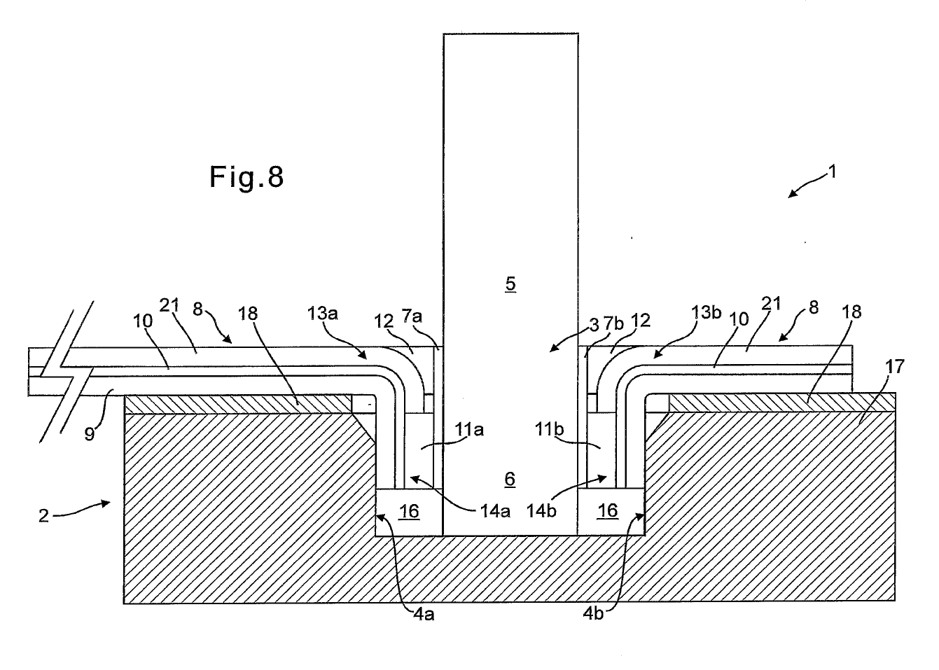

FIG. 8 an illustration similar to FIG. 5, wherein, however, the receiving recess flares upwardly,

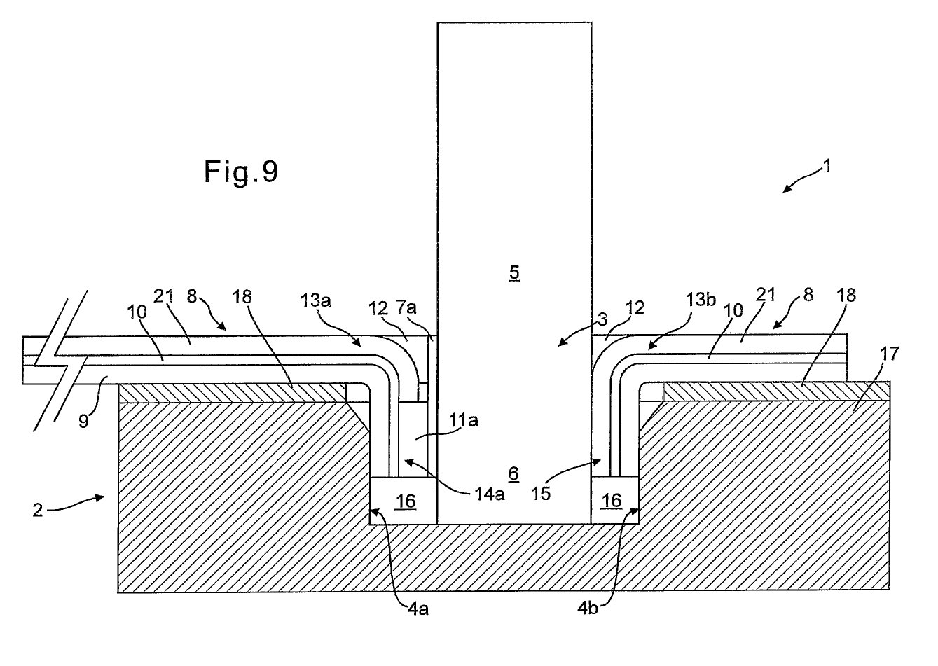

FIG. 9 an illustration similar to FIG. 6, wherein, however, the receiving recess flares upwardly,

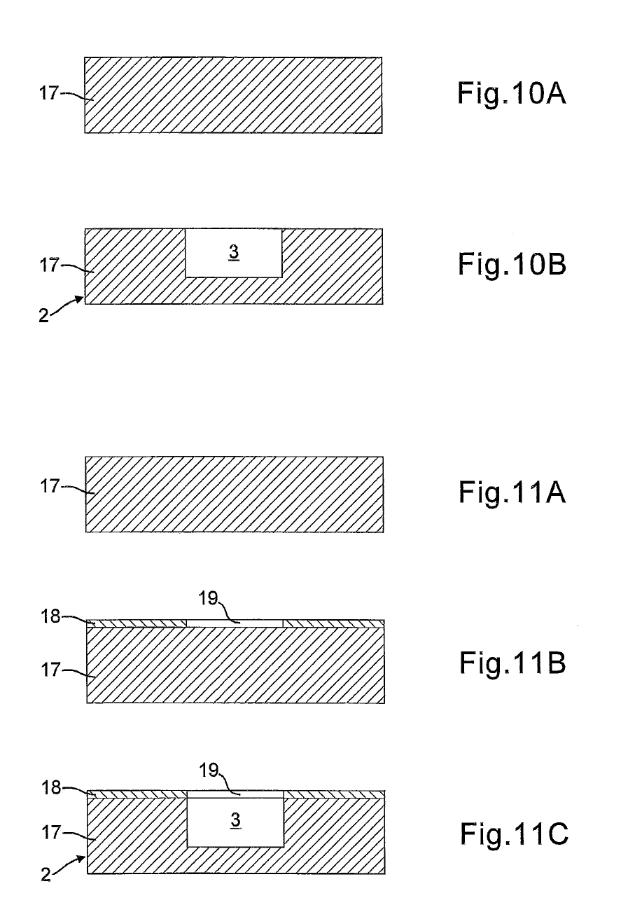

FIGS. 10A and 10B Process steps for manufacturing a first illustrative embodiment of the first microstructure piece,

FIGS. 11A-110 Process steps for manufacturing a second illustrative embodiment of the first microstructure piece,

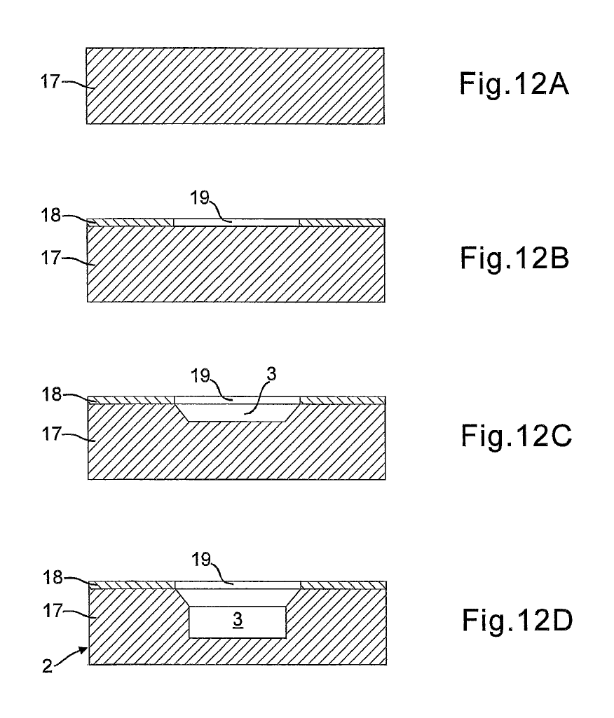

FIG. 12A-12D Process steps for manufacturing a third illustrative embodiment of the first microstructure piece,

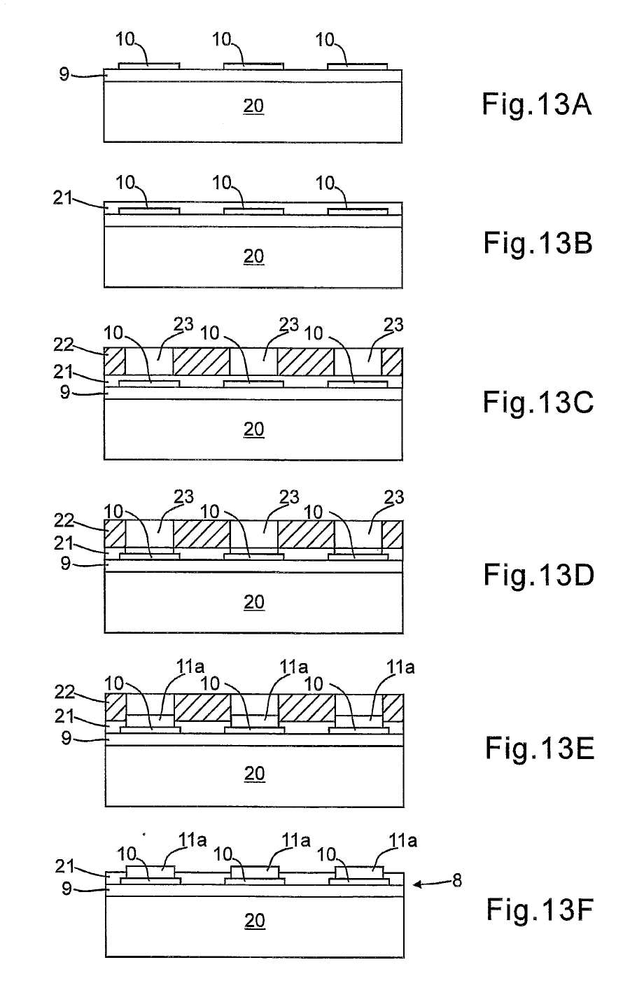

FIG. 13A-13F Process steps for manufacturing a flexible flat band cable,

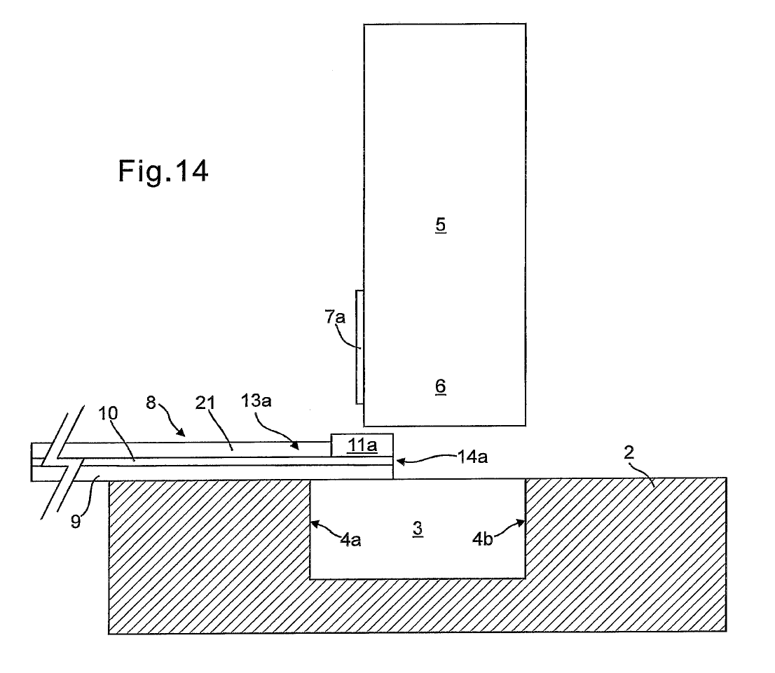

FIG. 14 the microstructure of FIG. 1 in a preassembly position,

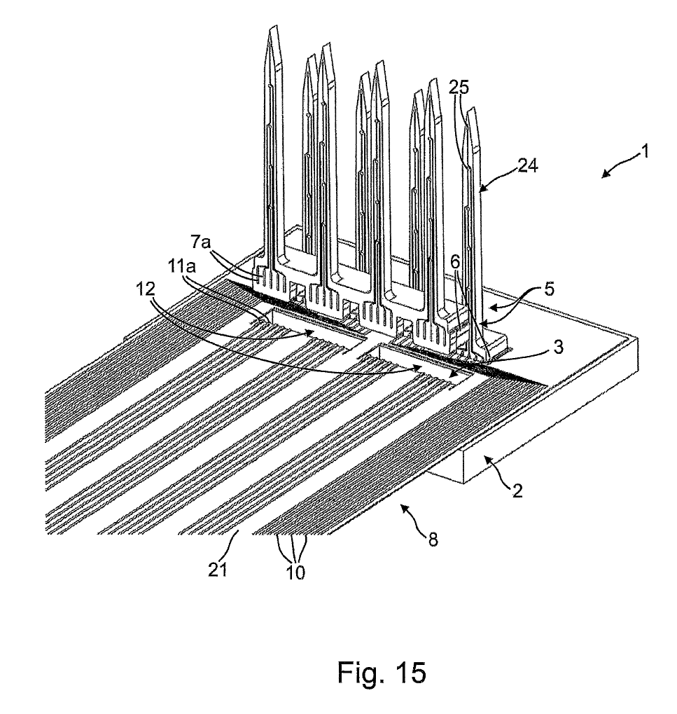

FIG. 15 a microstructure having one first and two second microstructure pieces, which in each case has a plurality of needle-like shafts, and

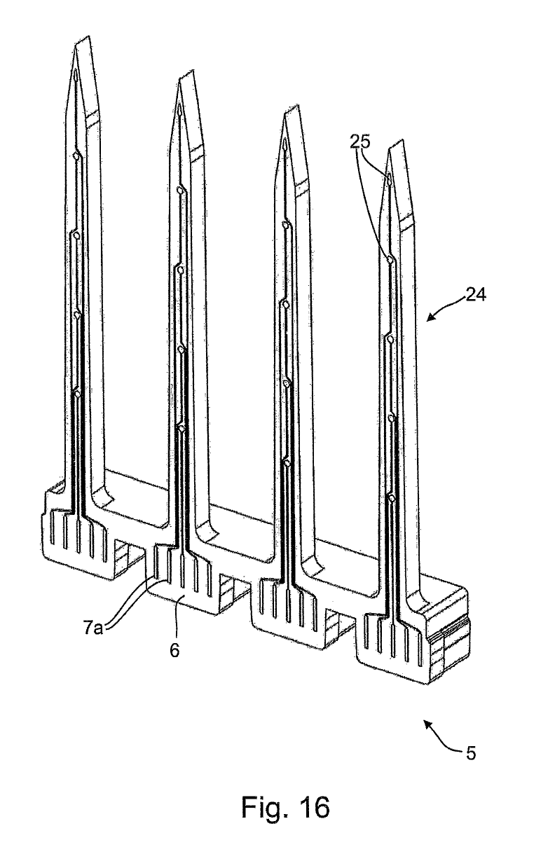

FIG. 16 a side view of the second microstructure piece.

A microstructure designated in its entirety with 1 comprises a first, approximately disc- or plate-shaped microstructure piece 2, in the surface of which is formed a receiving recess 3. The receiving recess 3 has an approximately rectangular opening and is delimited by side walls 4a, 4b and a floor.

The microstructure 1 further comprises at least one second microstructure piece 5, which is also approximately disc- or plate-shaped and has a connecting region 6 fitting into the receiving recess 3, which is aligned in the receiving recess 3. A segment of the second microstructure piece 5 arranged in elongation of the connecting region 6 is located outside the receiving recess 3.

The connecting region 6 has several contact elements 7a, 7b inside the receiving recess 3, which are connected to electrical conductors not shown in any greater detail in the drawing, which extend on the surface and/or into the interior of the second microstructure piece 5 and which can be connected to a sensor and/or an actuator, an electrode, or another electrical component present on the segment of the second microstructure piece located outside the receiving recess 3.

It can be discerned in FIGS. 1-8 that the second microstructure piece 5 is aligned with its plane of extension approximately orthogonal to the plane of lengthwise extension of the first microstructure piece 2.

The microstructure 1 has a flat, flexible cable 8 for electrically connecting the contact elements 7a, 7b to an electric circuit such as a measured value acquisition device and/or a driver spaced apart from the microstructure pieces 2, 5. Said cable has a flat substrate layer 9 made of an electrically insulating material, on which are arranged at a distance from the surface of said substrate layer 9 strip conductors 10, each of which is electrically connected to an exposed counter-contact element 11a, 11b on the surface of the cable 8. Preference is given to the substrate layer 9 being composed of a polymer material such as polyamide.

In the cable 8, provision is made of a number of perforations 12 corresponding to the number of receiving recesses 3, which perforations 12 penetrate the cable 8 perpendicular to its plane of extension. However, it is also conceivable for the number of perforations of the cable 8 to be smaller than the number of receiving recesses 3. The cross-sectional dimensions of the perforations 12 are dimensioned in such a way that the connecting region 6 is in each case insertable in its associated perforation 12.

At each edge region 13a, 13b surrounding the individual perforations 12, on the cable 8 is integrally formed at least one tongue 14a, 14b having the counter-contact element 11a, 11b on a site spaced apart from the respective edge region 13a, 13b. It can be discerned in FIG. 1 that the tongue 14a is arranged between the connecting region 6 and a first side wall 4a of the receiving recess 3, where it extends approximately parallel to the first side wall 4a and the contact element 7a. The front side of the tongue 14a with its counter-contact element 11a thus comes to lie on the contact element 7a of the connecting region 6 facing said counter-contact element. The back side of the tongue 14a lies flat on the first side wall 4a.

Adjacent to a first edge region 13a of the perforation 12, the tongue 14a has a curvature that abuts on a segment of the cable 8 running parallel to the surface of the first microstructure piece 2. In FIG. 1 it is clearly discernible that the free end region of the tongue 14a comprising the counter-contact element 11a is aligned approximately orthogonal to the surface of the first microstructure piece 2 and the segment of the cable 8 located thereon. A second side wall 4b of the receiving recess 3 opposite the first side wall 4a and running approximately parallel thereto abuts with the connecting region 6 in the illustrative embodiment shown in FIG. 1.

In FIG. 2 it can be discerned that the cable 8 can also have tongues 14a, 14b integrally formed on said cable 8 on both sides of the second microstructure piece 5. A first tongue 14a corresponds to the tongue 14a in FIG. 1. A second tongue 14b is connected to a second edge region 13b of the perforation 12 opposite the first edge region 13a. The second tongue 14b is arranged between the connecting region 6 and the second side wall 4b of the receiving recess 3. On its front side with its counter-contact element 11b, the second tongue 14b comes to rest on a second contact element 7b of the connecting region 6 facing said counter-contact element. The back side of the second tongue 14b lies flatly on the second side wall 4b.

In the illustrative embodiment shown in FIG. 3, in lieu of the second tongue 14b a tongue element 15 formed by a segment of the cable 8 is arranged between the connecting region and the second side wall 4b. Adjacent to the second edge region 13a, the tongue element 15 has a curvature in abutment with the segment of the cable 8 that runs parallel to the surface of the first microstructure piece 2.

The tongue element 15 is electrically insulated from the microstructure pieces 2, 5 by the substrate layer 9. The strip conductors 10 and the counter-contact element 11a in each case are spaced apart from the first microstructure piece 2 by the electrically insulating substrate layer 9. In FIGS. 1-3 it can be further discerned that a free space 16 can be present between the free ends of the tongues 14a, 14b and/or between the free end of the tongue element 15 on one hand and the floor of the receiving recess 3 on the other hand.

In FIGS. 4-6 it can be discerned that the first microstructure piece 2 has a substrate 17 on which is arranged an adhesive layer 18 to which the cable 8 with the substrate 9 flatly adheres. Preference is given to the adhesive layer 18 being a polymer layer. By means of the adhesive layer 18, the cable 8 adhering thereto is fixedly mounted in its position relative to the first microstructure piece 2.

In the illustrative embodiments shown in FIGS. 7-9, the first side wall 4a and the second side wall 4b of the receiving recess 3 each have an inclined surface and a step adjacent to the curvature in each case, where the clearance between the side wall 4a, 4b and each wall of the connecting region 6 opposite the side wall increases from the floor of the receiving recess 3 to the surface of the first microstructure piece 2.

The first microstructure piece 2 is manufactured before the microstructure 1 illustrated in FIGS. 1-3 can be assembled. To this end, provision is initially made of an approximately disc-shaped substrate 17 such as a semiconductor substrate (FIG. 10A). Next the receiving recess 3 is formed in the substrate 17 by area-wise removal of the material (FIG. 10B).

In the manufacturing of the microstructure 1 illustrated in FIGS. 4-9, an adhesive layer 18 covering the entire surface is deposited on the substrate 17 shown in FIG. 11A. This adhesive layer is structured at the site on which the receiving recess 3 will eventually be present by forming an opening 19 (FIG. 11B). Afterwards the receiving recess 3 is created by the removal of the substrate material in the opening 19 (FIG. 11C).

In the manufacturing of the microstructure 1 illustrated in FIGS. 7-9, after the formation of an opening 19 in the adhesive layer 18 (FIG. 12B), a first downwardly narrowing and approximately funnel-shaped segment of the receiving recess 3 is formed in the substrate by removing substrate material from the opening 19, for example by etching (FIG. 12C). Afterwards a second segment of the receiving recess 3 is formed below the first segment (FIG. 12D).

In another procedural step, provision is made of the second microstructure piece 5, which has the connecting region 6 fitting into the receiving recess 3 and on which the contact elements 7a are arranged.

Further provision is made of the cable 8. To this end, the flat substrate layer 9 made of the electrically insulating material is deposited on an auxiliary substrate 20 (FIG. 13A). Strip conductors 10 spaced apart from one another are formed on the substrate layer 9.

In can be discerned in FIG. 13B that a top layer 21 also made of an electrically insulating material is deposited over the entire surface of the substrate layer 9 covered with the strip conductors 10. On the top layer 21 is applied a photomask 22, which has interruptions 23 over the places where the counter-contact elements 11a will eventually be (FIG. 13C). For removing the areas of the top layer 21 present within the interruptions 23, the photomask 22 and the interruptions 23 are brought into contact with an etchant for the top layer 21 (FIG. 13D).

Afterwards each of the regions of the strip conductors 10 located within the interruptions 23 is covered with a counter-contact element 11a, which projects above the top layer 21 surface facing away from the auxiliary substrate 20 (FIG. 13E). Afterwards the photomask 22 is removed from the top layer 21 (FIG. 13F). In its base region, each individual counter-contact element 11a is uninterruptedly surrounded by the top layer 21 in a plane running parallel to the plane of extension of the substrate layer 9. The cable 8 thus obtained is separated from the auxiliary substrate 20.

As can be discerned in FIG. 14, the cable 8 is now positioned in a preassembly position in relation to the receiving recess 3 in such a way that the tongue 14a overlaps the receiving recess 3 and is capable of being deflected in the receiving recess 3. The second microstructure piece 5 is then positioned on the first microstructure piece 2 in such a way that the connecting region 6 is aligned outside and opposite the receiving recess 3. The connecting region 6 is now introduced in the receiving recess 3, wherein the connecting region 6 elastically and/or plastically deflects the free end of the tongue 14a to the floor of the receiving recess 3. Each counter-contact element 11a thus comes into contact with its associated contact element 7a, wherein the restoring force of the elastic tongue 14a presses the counter-contact elements 11a onto the contact elements 7a (FIG. 1). The microstructure pieces 2, 5 and the cable 8 are now fixedly mounted in their position relative to one another.

In the illustrative embodiment shown in FIGS. 15 and 16, the second microstructure piece 5 has several connecting regions 6, on each of which is arranged an approximately needle-shaped shaft piece 24. Each shaft piece 24 has several strip conductor-like electrically conductive regions, each of which is electrically connected to one of the contact elements 7a, 7b on one of its ends and has an exposed electrode 25 on its end remote from the connecting region 6. In FIG. 15, one of the two second microstructure pieces 5 is positioned in the preassembly position. The other second microstructure piece 5 is inserted in its associated receiving recess 3 of the first microstructure piece 2.

1. Process for the assembly of a microstructure (1) comprising the following steps:
Provision of a first microstructure piece (2) having a surface in which at least one receiving recess (3) is formed,
Provision of at least one second microstructure piece (5) having a connecting region (6) fitting into the receiving recess (6), on which at least one electric contact element (7a, 7b) is arranged,
Provision of a flexible cable (8) comprising at least one flat substrate layer (9) made of an electrically insulating material and at least one strip conductor (10) arranged thereon, wherein the cable (8) has at least one tongue (14a, 14b) on which is arranged at least one counter-contact element (11a, 11b) connected to the strip conductor (10),
Positioning of the cable (8) and the microstructure pieces (2, 5) in a preassembly position in such a way that the connecting region (6) is opposite the receiving recess (3) and the tongue (14a, 14b) is aligned between the connecting region (6) and the receiving recess (3),
Displacement of the first microstructure piece (2) and the second microstructure piece (5) towards each other in such a way that the connecting region (6) is introduced in the receiving recess (3) and in doing so the at least one tongue (14a, 14b) is deflected in the receiving recess (3) in such a way that the at least one counter-contact element (11a, 11b) contacts the at least one contact element (7a, 7b), and
Fixedly mounting the first microstructure piece (2) relative to the second microstructure piece (5).

2. Process as in claim 1, characterized in that the flexible cable (8) is positioned against the first microstructure piece (2) in such a way that the at least one contact element (7a, 7b) and the at least one counter-contact element (11a, 11b) are spaced apart from the first microstructure piece (2) by the substrate layer (9).

3. Process as in claim 1 or 2, characterized in that the first microstructure piece (2) has, on its surface facing the cable (8) in the preassembly position, an adhesive layer (18), and further characterized in that the first microstructure piece (2) in the preassembly position and the cable (8) are displaced towards each other in such a way that the cable (8) touches and adheres to the adhesive layer (18).

4. Process as in any one of claims 1 through 3, characterized in that the cable (8) has, on its surface facing the first microstructure piece (2) in the preassembly position, an adhesive layer (18), and further characterized in that the first microstructure piece (2) in the preassembly position and the cable (8) are displaced towards each other in such a way that the first microstructure piece (2) touches and adheres to the adhesive layer (18).

5. Process as in any one of claims 1 through 4, characterized in that the cable (8) has at least one perforation (12), wherein the at least one tongue (14a, 14b) is connected to the edge region (13a, 13b) of said perforation (12) in such a way that it extends into the perforation (12) and/or overlaps the latter at least area-wise, further characterized in that the cable (8) in the preassembly position is positioned relative to the receiving recess (3) in such a way that the perforation (12) overlaps the receiving recess (3), and still further characterized in that the connecting region (6), under the deflection of the tongue (14a, 14b), is inserted through the perforation (12) into the receiving recess (3).

6. Method as in any one of claims 1 through 5, characterized in that the second microstructure piece (5) has at least one shaft piece (24) connected to the connecting region (6) and having at least one electrically conductive region electrically connected to the contact element (7a, 7b).

7. Microstructure (1) with a first microstructure piece (2), in the surface of which at least one receiving recess (3) is formed, with at least one second microstructure piece (5) having a connecting region (6) engaging in the receiving recess (3) and on which is arranged at least one electrical contact element (7a, 7b), with at least one tongue (14a, 14b) having at least one counter-contact element (11a, 11b) and which is arranged between the connecting region (6) and a side wall (4a, 4b) of the receiving recess (3) facing the latter in such a way that the contact element (7a, 7b) of the connecting region (6) contacts the counter-contact element (11a, 11b) of the tongue (14a, 14b), with a flexible cable (8) having at least one flat substrate layer (9) made of an electrically insulating material and at least one strip conductor arranged thereon and electrically connected to the counter-contact element (11a, 11b) and which is connected at a place spaced apart from the tongue (14a, 14b) to an electric circuit spaced apart from the first microstructure piece (2), characterized in that the tongue (14a, 14b) is integrally configured with the cable (8).

8. Microstructure (1) as in claim 7, characterized in that the at least one strip conductor (10) and the at least one counter-contact element (11a, 11b) are spaced apart from the first microstructure piece (2) by the substrate layer (9).

9. Microstructure (1) as in claim 7 or 8, characterized in that the cable (8) has at least one perforation (12) that penetrates the cable (8) perpendicular to its plane of extension, further characterized in that the tongue (14a, 14b) is aligned perpendicular to the plane spanned by the perforation (12) and connected to an edge region of the perforation (12) at its end remote from the second microstructure piece (5).

10. Microstructure (1) as in any one of claims 7 through 9, characterized in that on the first microstructure piece (2) is arranged an adhesive layer (18) facing the cable (8), by means of which the cable (8) adheres to the first microstructure piece (2).

11. Microstructure (1) as in claim 9 or 10, characterized in that

12. the tongue (14a, 14b) has a curvature between the edge region of the perforation (12) and the contact element (7a, 7b), further characterized in that the side wall (4a, 4b) of the receiving recess (3) facing the tongue (14a, 14b) has an inclined surface and/or a step adjacent to the curvature where the clearance between the side wall (4a, 4b) and a wall of the connecting region (6) opposite said side wall (4a, 4b) increases starting from the floor of the receiving recess (3) to the surface of the first microstructure piece (2).

13. 12. Microstructure (1) as in any one of claims 9 through 11, characterized in that the cable (8) has, at its edge region (13b) of the perforation (12) spaced apart from and oppositely arranged relative to the tongue (14a, 14b), at least one tongue element (15) formed by a segment of the cable (8), which is arranged between the connecting region (6) and another side wall (4b) of the receiving recess (3) facing the former.

14. Microstructure (1) as in any one of claims 9 through 12, characterized in that the connecting area (6) has at least one first contact element (7a) and one second contact element (7b), which are arranged on sides of the connecting region (6) facing one another, further characterized in that the cable (8) has, on a first edge region (13a) of the perforation (12) facing the first contact element (7a), a first tongue (14a) having at least one first counter-contact element (11a) and, on a second edge region (13a) of the perforation (12) facing the second contact element (7b), a second tongue (14b) having at least one second counter-contact element (11b), still further characterized in that the first tongue (14a) is arranged between the connecting region (6) and a first side wall (4a) of the receiving recess (3) in such a way that the first contact element (7a) contacts the first counter contact element (11a), and even still further characterized in that the second tongue (14b) is arranged between the connecting region (6) and a second side wall (4b) of the receiving recess (3) in such a way that the second contact element (7b) contacts the second counter-contact element (11b).

15. Microstructure (1) as in any one of claims 7 through 13, characterized in that the second microstructure piece (5) has at least one shaft piece (24) connected to the connecting region (6) and having at least one electrically conductive region electrically connected to the contact element (7a, 7b).
